(19) United States
(12) Patent Application Publication
(10) Pub. No.: US 2026/0239624 A1
(43) Pub. Date: Aug. 13, 2026

(54) CROSS-COUPLED DIFFERENTIAL FeFET BIT-CELL CIRCUIT

(71) Applicant: National University of Singapore, Singapore (SG)

(72) Inventors: Jianze Wang, Singapore (SG); Samarth Jain, Singapore (SG); Xuanyao Fong, Singapore (SG)

(21) Appl. No.: 19/533,576

(22) Filed: Feb. 9, 2026

(30) Foreign Application Priority Data
Feb. 10, 2025 (SG) 10202500366S

(51) Int. Cl. H10B 51/40; G11C 11/22; H10B 51/30; H10B 51/50; H10B 80/00

(52) U.S. Cl. CPC H10B 51/40; G11C 11/2255; G11C 11/2257; H10B 51/30; H10B 51/50; H10B 80/00

(57) ABSTRACT

This document describes a differential memory bit-cell comprising a pair of cross-coupled ferroelectric field-effect transistors (FeFETs) and a pair of access transistors whereby the bit-cell may be configured in both volatile and non-volatile mode.

### CROSS-REFERENCE TO RELATED APPLICATION

This application claims the benefit of priority to Singapore patent application no. 10202500366S which was filed on 10 Feb. 2025, the contents of which are hereby incorporated by reference in its entirety for all purposes.

### TECHNICAL FIELD

This application relates to a differential memory bit-cell comprising a pair of cross-coupled ferroelectric field-effect transistors (FeFETs) and a pair of access transistors whereby the bit-cell may be configured in both volatile and non-volatile mode.

### BACKGROUND

Various emerging non-volatile memory (eNVM) technologies, including resistive random-access memory (RRAM), phase-change memory (PCM), and spin-transfer torque magnetic random-access memory (STT-MRAM), have been proposed as alternatives to static random-access memory (SRAM) for embedded memory applications due to their normally-off characteristics. While such eNVM technologies may reduce leakage power compared with CMOS-based SRAM, they generally suffer from disadvantages including relatively high write energy consumption, long write latency, and limited endurance.

To address these issues, non-volatile SRAM (nvSRAM) architectures have been investigated by those skilled in the art. nvSRAM architectures typically combine conventional CMOS SRAM circuitry with non-volatile memory elements in an attempt to achieve both the fast access speed of SRAM and the non-volatility of eNVM devices. However, such approaches generally require explicit backup and restore operations in order to transfer data between the volatile latch and the non-volatile elements when the system enters and exits low-power or sleep states. This backup and restore operations introduce additional energy consumption and latency, which are undesirable in power-constrained applications such as Internet-of-Things (IoT) devices.

Ferroelectric field-effect transistors (FeFETs) have been proposed as an alternative type of eNVM device due to their potential for low-power operation, high switching speed, and improved endurance. However, FeFET-based nvSRAM designs tend to exhibit increased circuit area overheads. Additionally, existing differential FeFET-based nvSRAM cells that employ reconfigurable FeFET structures typically require multiple ferroelectric gate stacks formed over a single channel region. This in turn causes the overall fabrication complexity of the circuit to increase.

As such, those skilled in the art are constantly looking for memory bit-cell architectures that support non-volatile data retention while exhibiting low energy consumption, reduced latency, are compatible with standard semiconductor fabrication processes, and avoids reliance on explicit backup and restore operations.

### SUMMARY

In one aspect, the present disclosure describes a differential bit-cell circuit comprising a first field-effect transistor (FET) and a second FET, wherein the first and second FETs each have a gate terminal coupled to a word line. The circuit also includes a first ferroelectric field-effect transistor (FeFET) and a second FeFET, wherein the first and second FeFETs are cross-coupled to form a bistable latch such that: a gate terminal of the first FeFET is electrically coupled to a drain terminal of the second FeFET, a gate terminal of the second FeFET is electrically coupled to a drain terminal of the first FeFET, a source terminal of the first FeFET is electrically coupled to a first source line, and a source terminal of the second FeFET is electrically coupled to a second source line. Additionally, the first FET is connected between the drain terminal of the first FeFET and a first bit line, and the second FET is connected between the drain terminal of the second FeFET and a second bit line. Furthermore, the first FeFET and the second FeFET are programmable to store complementary ferroelectric polarization states corresponding to complementary threshold voltages of the first FeFET and the second FeFET. In response to activation of the word line, the first and second FETs then electrically couple the drain terminals of the first and second FeFETs to the first and second bit lines respectively.

According to embodiments of this aspect, the first bit line and the first source line are biased to a first write voltage, and the second bit line and the second source line are biased to a second write voltage different from the first write voltage, such that the first FeFET and the second FeFET are programmed with gate-to-source voltages of opposing polarity.

According to embodiments of this aspect, in response to de-activation of the word line, the first and second FETs electrically decouple the first and second bit lines from the drain terminals of the first and second FeFETs respectively, such that first and second FeFETs maintain complementary voltage levels at the drain terminals of the first and second FeFETs in accordance with the complementary threshold voltages of the first and second FeFETs.

According to embodiments of this aspect, the differential bit-cell circuit further comprises a pre-charge circuit electrically coupled to the first and second bit lines, the pre-charge circuit configured to bias the first and second bit lines to a common pre-charge voltage. The bit-cell circuit also includes a voltage sensing circuit electrically coupled to the first and second bit lines, the voltage sensing circuit configured to detect a voltage difference between the first and second bit lines.

According to embodiments of this aspect, the differential bit-cell circuit further comprises a pre-charge polarization circuit electrically coupled to the first and second bit lines and the first and second source lines, the pre-charge polarization circuit configured to bias the first and second bit lines and the first and second source lines such that the first and second FeFETs are programmed to a same ferroelectric polarization state, wherein the pre-charge polarization circuit is electrically decouplable from the first and second bit lines and the first and second source lines such that, when the first and second FeFETs are in the same ferroelectric polarization state, a logic state of the bit-cell circuit is represented by complementary voltage levels at the drain terminals of the first and second FeFETs.

According to embodiments of this aspect, the pre-charge polarization circuit is configured to bias the first and second bit lines and the first and second source lines such that the first and second FeFETs are programmed to different ferroelectric polarization states, each corresponding to different threshold voltages.

According to embodiments of this aspect, the first and second FeFETs each comprise a ferroelectric electric layer comprising hafnium zirconium oxide (HZO) or lead zirconate titanate (PZT).

According to embodiments of this aspect, each of the first FeFET and the second FeFET further comprises a substrate terminal coupled to a back-bias line configured to tune a threshold voltage of the first and second FeFETs.

According to embodiments of this aspect, a memory array circuit is also disclosed whereby the memory array circuit comprises a plurality of differential bit-cell circuits as described in the embodiments above whereby the plurality of differential bit-cell circuits are arranged in rows and columns. In this embodiment, differential bit-cell circuits in a same row share a common word line, and differential bit-cell circuits in a same column share a first bit line, a second bit line, a first source line, and a second source line.

In another aspect, the present disclosure describes a method for operating a differential bit-cell circuit. The method comprises the steps of providing the differential bit-cell circuit that comprises a first field-effect transistor (FET) and a second FET, wherein the first and second FETs each have a gate terminal coupled to a word line, a first ferroelectric field-effect transistor (FeFET) and a second FeFET, wherein the first and second FeFETs are cross-coupled to form a bistable latch such that a gate terminal of the first FeFET is electrically coupled to a drain terminal of the second FeFET, a gate terminal of the second FeFET is electrically coupled to a drain terminal of the first FeFET, a source terminal of the first FeFET is electrically coupled to a first source line, and a source terminal of the second FeFET is electrically coupled to a second source line, wherein the first FET is connected between the drain terminal of the first FeFET and a first bit line, and the second FET is connected between the drain terminal of the second FeFET and a second bit line. The method also comprises the steps of programming the first FeFET and the second FeFET to store complementary ferroelectric polarization states corresponding to complementary threshold voltages of the first FeFET and the second FeFET; and activating the word line to electrically couple the drain terminals of the first and second FeFETs to the first and second bit lines respectively.

### BRIEF DESCRIPTION OF THE DRAWINGS

Various embodiments of the present disclosure are described below with reference to the following drawings:

FIG. 1 illustrates a front view of a FeFET as known to one skilled in the art;

FIG. 2 illustrates two plots showing the drain current versus gate voltage of the FeFET illustrated in FIG. 1 with the two plots corresponding to different polarization states of the FeFET;

FIG. 3 illustrates a circuit diagram of the differential bit-cell with the access transistors being each coupled to their own word line in accordance with embodiments of the disclosure;

FIG. 4 illustrates a circuit diagram of the differential bit-cell with the access transistors being each coupled to a common word line in accordance with embodiments of the disclosure;

FIG. 5 illustrates a voltage biasing arrangement applied to the differential bit-cell circuit to program a write logic “1” in accordance with an embodiment of the disclosure;

FIG. 6 illustrates a voltage biasing arrangement applied to the differential bit-cell circuit to program a write logic “0” in accordance with an embodiment of the disclosure;

FIG. 7 illustrates a voltage biasing arrangement applied to the differential bit-cell circuit to retain a stored logic value in accordance with an embodiment of the disclosure;

FIG. 8 illustrates a voltage biasing arrangement applied to the differential bit-cell circuit to trigger the circuit to perform a read operation in accordance with an embodiment of the disclosure;

FIG. 9 illustrates a top view of a memory array comprising a plurality of the differential bit-cell circuits illustrated in FIG. 3 with various peripheral circuits in accordance with embodiments of the disclosure;

FIG. 10 illustrates a top view of the layout of the differential bit-cell circuit illustrated in FIG. 3;

FIG. 11 illustrates temporal waveforms of control and data signals applied to the memory circuit of FIG. 9 during write and read operations according to an embodiment of the disclosure;

FIG. 12a illustrates voltages at nodes Q and QB of the differential bit-cell circuit illustrated in FIG. 3 during a logic read “1” operation under different write bias conditions;

FIG. 12b illustrates voltages at nodes Q and QB of the differential bit-cell circuit illustrated in FIG. 3 during a logic read “0” operation under different write bias conditions;

FIG. 12c illustrates ferroelectric polarization levels of the FeFETs and a polarization difference of the FeFETs during a logic read “0” operation under different write bias conditions;

FIG. 12d illustrates ferroelectric polarization levels of the FeFETs and a polarization difference of the FeFETs during a logic read “1” operation under different write bias conditions;

FIG. 12e illustrates write and read energies of the differential bit-cell circuit under different write and read bias conditions;

FIG. 12f illustrates sensing delay of the differential bit-cell under different write bias conditions;

FIG. 13a illustrates a voltage difference between nodes Q and QB of the differential bit-cell circuit during a logic read “1” operation under different write bias conditions and write pulse durations;

FIG. 13b illustrates a difference in ferroelectric polarization between the FeFETs of the differential bit-cell circuit during a logic read “1” operation under different write bias conditions and write pulse durations; and

FIG. 14 illustrates a flowchart showing a process for operating the differential bit-cell circuit.

### DETAILED DESCRIPTION

The following detailed description is made with reference to the accompanying drawings, showing details and embodiments of the present disclosure for the purposes of illustration. Features that are described in the context of an embodiment may correspondingly be applicable to the same or similar features in the other embodiments, even if not explicitly described in these other embodiments. Additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance as generally understood in the relevant technical field, e.g., within 10% of the specified value.

As used herein, the term “and/or” includes any and all combinations of one or more of the associated listed items.

As used herein, “comprising” means including, but not limited to, whatever follows the word “comprising”. Thus, use of the term “comprising” indicates that the listed elements are required or mandatory, but that other elements are optional and may or may not be present.

As used herein, “consisting of” means including, and limited to, whatever follows the phrase “consisting of”. Thus, use of the phrase “consisting of” indicates that the listed elements are required or mandatory, and that no other elements may be present.

As used herein, “cross-coupled to form a bistable latch” means that two transistors are electrically interconnected such that an output node of each transistor is coupled to a control terminal of the other transistor, thereby forming a feedback structure having two stable operating states.

In the context of various embodiments, the term “disposed on” relates to the placement or deposition of one material or layer onto the surface of another and may involve one or more types of deposition techniques.

In the context of various embodiments, the directional terms mentioned herein, such as “above” and “below” or “upper” and “lower” refer to directions as described with reference to the drawings. Therefore, the directional terms are only used for illustration and are not meant to limit the present disclosure.

It should be noted that although the terms first, second and third are used herein to describe various elements, these elements should not be limited by these terms as these terms are meant to only distinguish one element from another element. Thus, the first element described herein could be termed as a second element without departing from this disclosure.

Additionally, for the sake of brevity, extensive explanations of conventional techniques of fabricating semiconductor devices and integrated circuits are not described in detail herein. The tasks and processes described herein may also be integrated into a more comprehensive procedure with extra steps of features that are not elaborated upon in this document. Specifically, certain processes of fabricating semiconductor devices are well known to one skilled in the art hence, such processes will be omitted entirely.

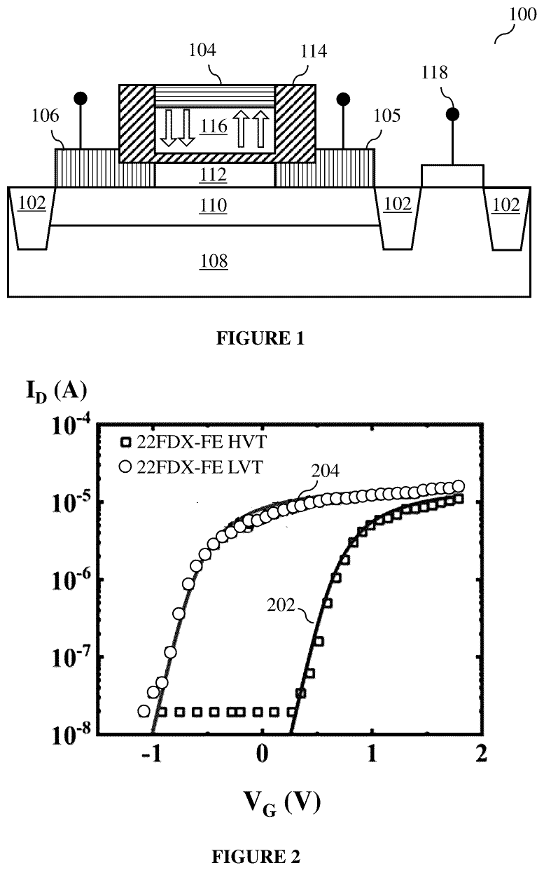

A cross-sectional view of a ferroelectric field-effect-transistor (FeFET) with a planar silicon-on-insulator (SOI) structure as known in the art is illustrated in FIG. 1. As shown in this figure, FeFET 100 is formed on substrate 108, which is separated from active silicon channel region 112 by buried oxide (BOX) layer 110. Shallow trench isolation (STI) regions 102 are provided laterally to isolate FeFET 100 from adjacent devices. Source region 106 and drain region 118 are formed as heavily doped regions (e.g., n+ silicon regions), and a gate stack is disposed above silicon channel region 112.

The gate stack includes gate electrode 104, insulator layer 114, and ferroelectric (Fe) layer 116 disposed between the gate electrode 104 and the insulator layer 114. In embodiments of the disclosure, ferroelectric layer 116 may comprise, but is not limited to, hafnium zirconium oxide (HZO) or lead zirconate titanate (PZT). Back-bias terminal 118 is electrically coupled to substrate 108 such that it may be used to apply a back-bias voltage to adjust a threshold voltage of FeFET 100. As shown in FIG. 1, the polarization state of ferroelectric layer 116 is represented schematically by arrows indicating the general orientation of the ferroelectric dipoles. When the polarization of Fe layer 116 is oriented downward, corresponding to a negative polarization state, positive bound charges accumulate near the interface between Fe layer 116 and insulator layer 114. This charge distribution modifies the electrostatic potential seen by channel layer 112 and reduces the threshold voltage of FeFET 100 to a lower threshold voltage state V_{th,L}. Under such a condition, the FeFET 100 turns on at a relatively lower gate voltage.

Conversely, when the polarization of Fe layer 116 is oriented upwards, corresponding to a positive polarization state, the bound charge distribution near FE-insulator interface is reversed. This increases the effective threshold voltage of FeFET 100 to a higher threshold voltage state, V_{th,H}. The difference between these two threshold voltage states, V_{th,L} and V_{th,H}, defines a memory window of FeFET 100. It should be noted that it is this memory window that enables the storage of logic information based on a retained polarization state at ferroelectric layer 116.

In a conventional FeFET bit-cell, binary logic states are represented by the threshold voltage state of the FeFET. In particular, a logic “1” may be stored by programming the FeFET to the low-threshold-voltage state V_{th,L}, while a logic “0” may be stored by programming the FeFET to the high-threshold-voltage state V_{th,H}. Hence, as the stored logic value can be preserved without continuous electrical bias, the polarization state of the ferroelectric layer is retained in the absence of power, thereby enabling the FeFET to operate as a non-volatile memory.

FIG. 2 illustrates two plots showing the drain current versus gate voltage (I_{D}-V_{G}) transfer characteristics of FeFET 100 as shown in FIG. 1 under different polarization states of the ferroelectric layer. As shown in FIG. 2, plot 202 corresponds to a I_{D}-V_{G} curve generated by a FeFET that has been configured to have a higher threshold voltage state (HVT), and plot 204 corresponds to a I_{D}-V_{G} curve generated by a FeFET that has been configured to have a lower threshold voltage state (LVT). The separation between the HVT and LVT curves (i.e., plots 202 and 204) represents a memory window of the FeFET, which arises from different polarization orientations of the ferroelectric layer. Based on plots 202 and 204, it can be seen that when the FeFET is in the LVT state, the FeFET exhibits a higher drain current at a given gate voltage compared with the HVT state, indicating that a FeFET in a LVT state has a reduced threshold voltage that is associated with a first polarization orientation of the ferroelectric layer.

It should be noted that for this simulation and analysis, the ferroelectric layer of the FeFET was modelled as a ferroelectric capacitor (FeCap) using a nucleation-limited switching (NLS) model. The electrical behaviour of the FeFET was then obtained by combining the FeCap model with a transistor model based on a BSIM-IMG formulation. The resulting composite model was able to capture both the ferroelectric polarization switching behaviour and the channel conduction characteristics of the underlying field-effect transistor. It was then determined that the modelled I_{D}-V_{G} characteristics were able to closely match experimentally reported data, indicating that the FeFET model was successfully calibrated to measured device behaviour and is indeed suitable for use in circuit-level simulations of FeFET-based memory cells.

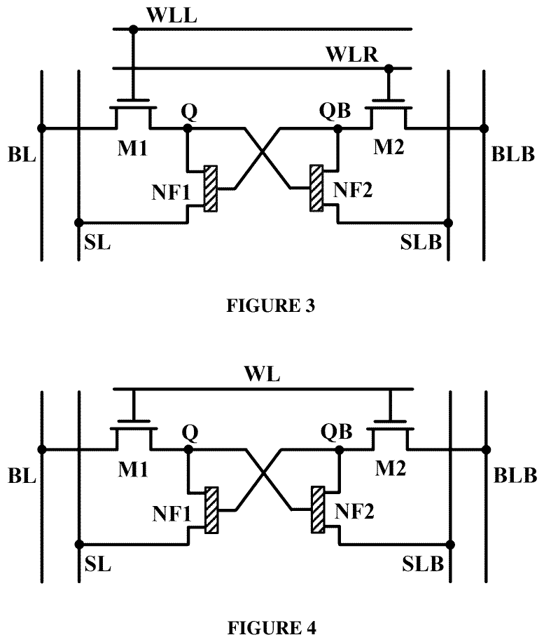

FIG. 3 illustrates a circuit diagram of a differential FeFET bit-cell. The bit-cell illustrated in this figure includes two transistors M1 and M2 and two ferroelectric field-effect transistors (FeFET) NF1 and NF2 arranged in a cross-coupled configuration. In embodiments of the disclosure, transistors M1 and M2 may comprise field-effect transistors configured as access transistors for selectively coupling FeFETs NF1 and NF2 to external signal lines. Transistors M1 and M2 may comprise, but is not limited to, p-type FETs, n-type FETs, or other types of similar semiconductor switching devices that may be suitable for implementing access transistor functionality.

As shown, the drain terminal of FeFET NF1 is electrically coupled to the gate terminal of FeFET NF2, and the drain terminal of FeFET NF2 is electrically coupled to the gate terminal of FeFET NF1, thereby forming a bistable latch that stores complementary logic states at nodes Q (i.e., at the drain terminal of FeFET NF1) and QB (i.e., at the drain terminal of FeFET NF2).

As shown in FIG. 3, transistors M1 and M2 are disposed between nodes Q and QB and differential bit lines BL and BLB, respectively. The gate terminals of transistors M1 and M2 are electrically coupled to individual word lines WLL and WLR respectively so that each of transistors M1 and M2 may be controlled separately. The word lines WLL and WLR are used for bit-cell selection and for linking nodes Q and QB with differential bit lines BL and BLB.

In operation, cross-coupled FeFETs NF1 and NF2 store the state of the bit-cell by retaining different ferroelectric polarization states corresponding to different threshold voltages. As further illustrated, source terminals of FeFETs NF1 and NF2 are electrically coupled to differential source lines SL and SLB, respectively. The differential source lines are configured to control source potentials of the FeFETs during write operations, thereby stabilizing programming of the FeFETs and reducing write energy consumption. Unlike arrangements in which source terminals of cross-coupled transistors are fixed to a common reference potential, the use of independently driven differential source lines enables a controlled gate-to-source voltage to be applied across each cross-coupled transistor during programming. When the cross-coupled transistors comprise cross-coupled FeFETs, this configuration is advantageous as it allows the polarization state of each FeFET to be set using a reduced voltage swing and with improved symmetry between complementary devices. As a result, write disturbance, leakage current during programming, and overall write energy are reduced relative to bit-cell architectures that do not employ differential source line control.

FIG. 4 illustrates a circuit diagram of a differential FeFET bit-cell similar to that shown in FIG. 3. In the embodiment shown in FIG. 4, transistors M1 and M2 are coupled to a common word line WL, rather than to separate word lines. The common word line WL is configured to selectively couple storage nodes Q and QB to differential bit lines BL and BLB during write and read operations.

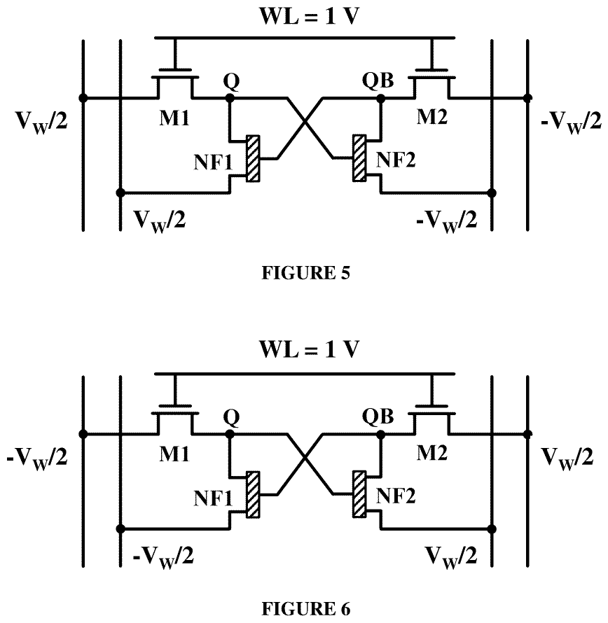

During a write operation for storing a logic “1”, the differential bit-cell is biased as illustrated in FIG. 5. Under such biasing conditions, the word line WL is driven to an active voltage level, e.g., WL=1 Volt, such that transistors M1 and M2 are switched on, thereby electrically coupling nodes Q and QB to differential bit lines BL and BLB, respectively. Simultaneously, differential write voltages are applied to bit lines BL, BLB and source lines SL, SLB such that bit line BL and corresponding source line SL are biased to a first write voltage of +W_{w}/2, while the complementary bit line BLB and the corresponding source line SLB are biased to a second write voltage of −V_{w}/2.

As a result of this biasing arrangement, a gate-to-source voltage V_{GS,NF1} of −V_{w} is established across FeFET NF1 and a gate-to-source voltage V_{GS,NF2} of +W_{w} is established across FeFET NF2. These opposing voltage polarities cause the ferroelectric layer of FeFET NF1 to be programmed to a first polarization state (−P_{FE}) and the ferroelectric layer of FeFET NF2 to be programmed to a complementary polarization state (+P_{FE}). The different polarization states correspond to different threshold voltages of FeFETs NF1 and NF2 respectively, thereby configuring FeFET NF1 to a lower threshold voltage state and FeFET NF2 to a higher threshold voltage state, or vice versa depending on device polarity.

Once programmed in this manner, the cross-coupled configuration of FeFETs NF1 and NF2 cause node Q to be driven toward a higher voltage level and node QB to be driven toward a lower voltage level, thereby representing a stored logic “1” state in the bit-cell. It should be noted that the ferroelectric polarization states of FeFETs NF1 and NF2 are retained after removal of the write voltages. As such, this allows the programmed logic “1” state to be preserved in a non-volatile manner. The use of differential biasing of both the bit lines and the source lines during the write operation further stabilizes the programming process and reduces write energy consumption by minimizing direct current flow through the bit-cell during polarization switching.

Similarly, during a write operation for storing a logic “0”, the differential bit-cell is biased in a complementary manner to the write logic “1” operation. Firstly, the word line WL is driven to an active voltage level to turn on transistors M1 and M2, thereby electrically coupling nodes Q and QB to differential bit lines BL and BLB, respectively. Differential write voltages are applied such that bit line BL and the corresponding source line SL are biased to −V_{w}/2, while the complementary bit line BLB and the corresponding source line SLB are biased to +V_{w}/2.

With this biasing arrangement, a gate-to-source voltage V_{GS,NF1} of +V_{w} is established across FeFET NF1 and a gate-to-source voltage V_{GS,NF2} of −V_{w} is established across FeFET NF2. These opposing voltage polarities cause the ferroelectric layer of FeFET NF1 to be programmed to a polarization state +P_{FE} and the ferroelectric layer of FeFET NF2 to be programmed to a complementary polarization state −P_{FE}. The respective polarization states correspond to different threshold voltages of FeFETs NF1 and NF2, thereby configuring the two FeFETs to complementary threshold voltage states.

Following programming, the cross-coupled configuration of FeFETs NF1 and NF2 cause node Q to be driven toward a lower voltage level and node QB to be driven toward a higher voltage level, thereby representing a stored logic “0” state in the bit-cell. Similarly, the programmed ferroelectric polarization states of FeFETs NF1 and NF2 are retained after removal of the applied write voltages thereby preserving the stored logic “0” state in a non-volatile manner. As with the previously described write logic “1” operation, the use of differential biasing of both the bit lines and the source lines stabilizes the programming process and reduces write energy consumption by limiting current flow through the bit-cell during polarization switching. It should be noted that during the write operation, i.e., for logic “1” or “0”, the voltage at bit-line BL is equal to the voltage at source line SL, and voltage at bit-line BLB is equal to the voltage at source line SLB.

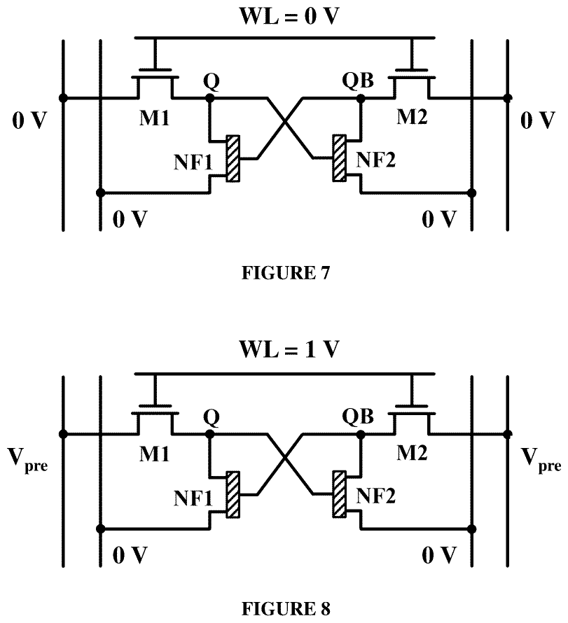

During a hold operation, the bit-cell is biased as illustrated in FIG. 7. Word line WL is firstly deactivated by driving it with an inactive voltage level, e.g., WL=0 Volts, thereby turning off transistors M1 and M2 and electrically isolating nodes Q and QB from differential bit lines BL and BLB. In addition, bit lines BL and BLB and differential source lines SL and SLB are maintained at a reference potential, e.g., at a ground potential.

Under these biasing conditions, the logic state of the bit-cell is maintained by the cross-coupled FeFETs NF1 and NF2. The stored memory state is represented by the retained ferroelectric polarization states of the ferroelectric layers within FeFETs NF1 and NF2, which correspond to the complementary threshold voltages of the two FeFETs. As the ferroelectric polarization states of FeFETs NF1 and NF2 are non-volatile, the stored logic value remains preserved even in the absence of applied voltages on the bit lines and source lines.

Accordingly, when the bit-cell is operated as a non-volatile static random-access memory (nvSRAM), no explicit backup or restore operation is required to transfer data between volatile storage nodes and non-volatile storage elements. The memory state is inherently retained in the polarization states of the cross-coupled FeFETs during normally-off operation. This contrasts with prior nvSRAM architectures that require separate backup and restore procedures when entering or exiting a low-power or sleep mode, thereby reducing both operational complexity and energy consumption in the disclosed bit-cell.

During a read operation, the bit-cell is biased as illustrated in FIG. 8. Prior to activating word line WL, both differential bit lines BL and BLB are pre-charged to a predetermined voltage Vpre and this may be done using a pre-charge circuit (not shown) electrically coupled to bit-lines BL and BLB. In this operation, differential source lines SL and SLB are maintained at a reference potential, such as ground potential. The pre-charge operation establishes substantially equal initial voltages on BL and BLB in preparation for differential sensing.

After pre-charging, word line WL is driven to an active voltage level to turn on transistors M1 and M2, thereby electrically coupling nodes Q and QB to differential bit lines BL and BLB, respectively. As a result, BL is discharged through FeFET NF1 and BLB is discharged through FeFET NF2. As NF1 and NF2 have different threshold voltages that are determined by their respective ferroelectric polarization states, the discharge currents through FeFETs NF1 and NF2 differ, causing BL and BLB to discharge at different rates.

The voltage difference that develops between BL and BLB during the discharge process is detected by a voltage sensing circuit such as, but not limited to, a differential sense amplifier (not shown) that is electrically coupled to bit lines BL and BLB. The sense amplifier interprets the relative voltage levels on BL and BLB to determine the stored logic state of the bit-cell. In this manner, the stored data is read without disturbing the retained ferroelectric polarization states of FeFETs NF1 and NF2, thereby enabling non-destructive readout of the memory state of the bit-cell.

In embodiments of the disclosure, the differential bit-cell may instead be operated in a volatile mode of operation. In this mode, FeFETs NF1 and NF2 are first programmed in advance to have the same ferroelectric polarization state that corresponds to a high threshold voltage (HVT). As a result, the threshold voltages of FeFETs NF1 and NF2 will be substantially equal, and the stored logic state of the bit-cell is no longer represented by a difference in the threshold voltage between the two FeFETs. Instead, the logic state is represented by the voltage levels at nodes Q and QB, in a manner similar to a conventional volatile latch.

During a volatile-mode write operation, word lines WL will be activated to turn on transistors M1 and M2, thereby coupling nodes Q and QB to differential bit lines BL and BLB, respectively. Write voltages VP and VPB are then applied to BL and BLB such that a voltage difference is established between the two-bit lines. When VP is greater than VPB, node Q is driven to a higher voltage level than node QB, thereby storing a logic “1” state. Conversely, when VP is less than VPB, node Q is driven to a lower voltage level than node QB, thereby storing a logic “0” state. As both FeFETs NF1 and NF2 are programmed to the same threshold voltage state, no non-volatile threshold voltage difference is used to represent data. Consequently, the stored logic state depends solely on the voltage levels at nodes Q and QB, which are maintained only while biasing voltages are applied to the bit lines and source lines of the bit-cell. When these biasing voltages are removed, the voltage levels at Q and QB will decay, and the stored logic value is not retained, thereby resulting in volatile operation.

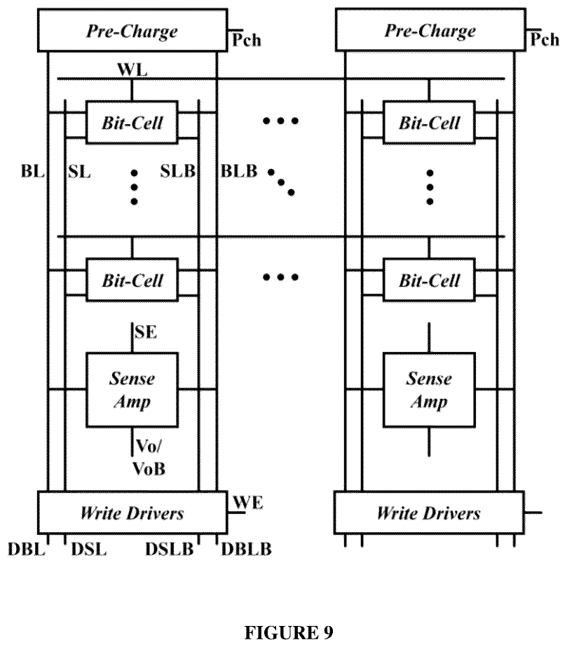

FIG. 9 illustrates a memory array architecture incorporating a plurality of the differential FeFET bit-cells together with associated peripheral circuits. The bit-cells are arranged in rows and columns such that bit-cells in a same row are electrically coupled to a common word line WL, and bit-cells in a same column share common differential bit lines BL and BLB and common differential source lines SL and SLB. This configuration enables row-based selection of bit-cells through the word line WL and column-based access through the shared bit lines and source lines.

A pre-charge circuit is provided at an upper portion of each column and is configured to pre-charge the differential bit lines BL and BLB prior to a read operation. The pre-charge circuit is enabled by a pre-charge control signal P_{ch}. At a lower portion of each column, a differential sense amplifier is provided for detecting a voltage difference between the differential bit lines BL and BLB during a read operation. In the illustrated embodiment, the sense amplifier comprises a latch-based sense amplifier of a type commonly used in static random-access memory (SRAM). The sense amplifier is enabled by a sense-enable signal SE and provides differential output signals Vo and VoB corresponding to a sensed logic state of a selected bit-cell.

Write drivers are coupled to the differential bit lines BL and BLB and the differential source lines SL and SLB for providing write voltages to a selected bit-cell during a write operation. The write drivers are enabled by a write-enable signal WE and receive input data signals DBL, DSL, DBLB, and DSLB, which determine voltage levels applied to the respective bit lines and source lines. Except for the use of differential source line control and, in some embodiments, the application of negative write voltages, the peripheral circuitry of the array is generally similar to that of a conventional SRAM array. Detailed circuit implementations of the peripheral blocks are omitted for brevity as it is assumed that one skilled in the art will be familiar with such circuits and/or blocks.

In embodiments of the disclosure, transistors M1 and M2 may be vertically stacked with the FeFETs NF1 and NF2 respectively to further reduce the footprint of the proposed differential bit-cell. In such embodiments, each of transistors M1 and M2 is formed above or below a corresponding FeFET along a vertical direction, thereby enabling a three-dimensional (3D) integration of the volatile and non-volatile devices within a single bit-cell. In other words, the transistor M1 may be vertically stacked with the FeFET NF1 and FET M2 may be vertically stacked with the FeFET NF2, such that each transistor and its corresponding FeFET are disposed in different device layers arranged along a vertical direction. This stacked configuration allows the lateral area of the bit-cell to be significantly reduced while preserving the cross-coupled electrical functionality between the storage nodes. In order for this stacked arrangement to be used, the transistors are not limited to silicon-based devices. In certain embodiments, transistors M1 and M2 and/or FeFETs NF1 and NF2 may be formed using alternative semiconductor materials, such as Zinc Oxide (ZnO).

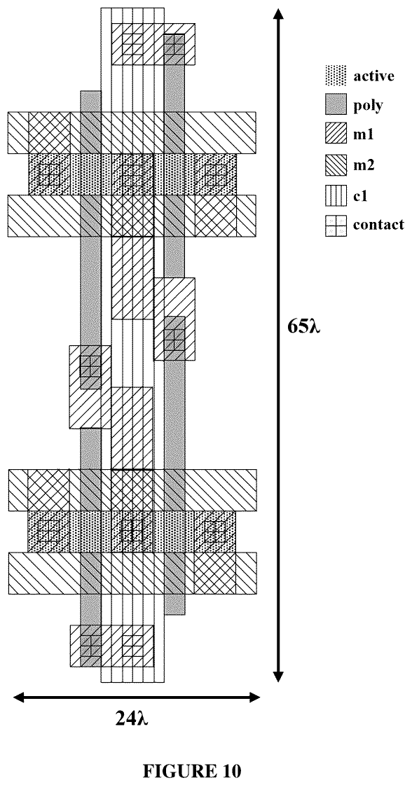

In embodiments of the disclosure, the differential FeFET bit-cell may be implemented using a GLOBALFOUNDRIES 22 nm process design kit (PDK) with A-based design rules, as illustrated in FIG. 10. As shown in this figure, the bit-cell may have a width of 24λ and a height of 65λ, resulting in a total cell area of 1560λ². For circuit evaluation and simulation, parasitic extraction may be performed on the FeFET bit-cell layout to account for layout-dependent resistive and capacitive parasitic, thereby enabling more accurate modelling of the electrical behaviour of the bit-cell in subsequent analyses.

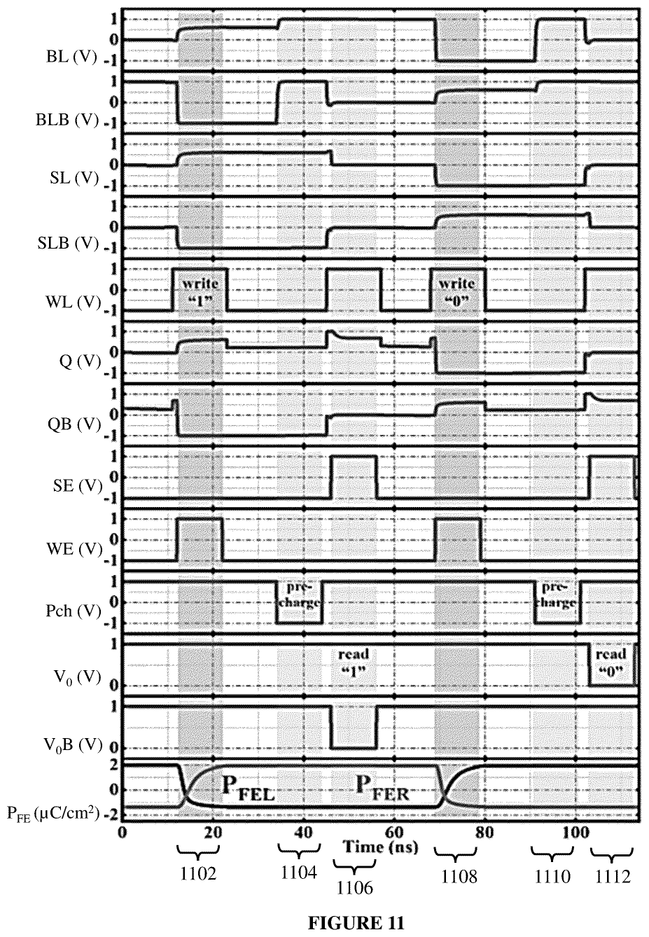

FIG. 11 illustrates transient simulation waveforms of various control and data signals for the differential FeFET bit-cell. In this simulation, a write pulse width of tₚ=10 ns and a write voltage magnitude of V_{w}=2 V is applied to ensure successful programming of the bit-cell. The plotted waveforms include the differential bit lines (BL and BLB), differential source lines (SL and SLB), word line (WL), internal nodes (Q and QB), sense-enable signal (SE), write-enable signal (WE), pre-charge control signal (Pch), output signals (Vo and VoB), and the corresponding ferroelectric polarization states (P_{FEL} and P_{FER}) of the two FeFETs. As shown, the bit-cell undergoes two successive write-read cycles to verify correct operation under both logic states.

During the first cycle, the bit-cell is programmed to store a logic “1,” as indicated by interval 1102. In this interval, the applied voltages on BL and BLB result in switching of the ferroelectric polarizations (P_{FEL} and P_{FER}. A read operation follows and includes a pre-charge phase and a sensing phase. During the pre-charge phase (shown as interval 1104), the pre-charge signal Pch is asserted, the word line WL is deactivated, and both bit-lines BL and BLB are pre-charged to the same voltage level. Subsequently, during the sensing phase (shown as interval 1106), the word line WL is activated, and the sense amplifier is enabled. As the polarization states of FeFETs NF1 and NF2 correspond to different threshold voltages, the discharge rates of Q and QB differ, with Q remaining at a higher voltage than QB. The resulting waveforms of Vo and VoB indicate that the stored logic value is correctly detected as “1.”

In the second cycle, the bit-cell is overwritten with a logic “0,” as shown in region 1108, followed by another read operation. The polarization waveforms P_{FEL} and P_{FER} confirm that the FeFETs are successfully reprogrammed to the complementary polarization states corresponding to the logic “0” condition. The subsequent read operation again includes a pre-charge phase (shown as interval 1110) and a sensing phase (shown as interval 1112), and the output waveforms Vo and VoB correctly reflect the newly written logic value. These results demonstrate that the proposed differential FeFET bit-cell can be reliably written and read for both logic states, thereby validating the functional operation of the disclosed memory architecture.

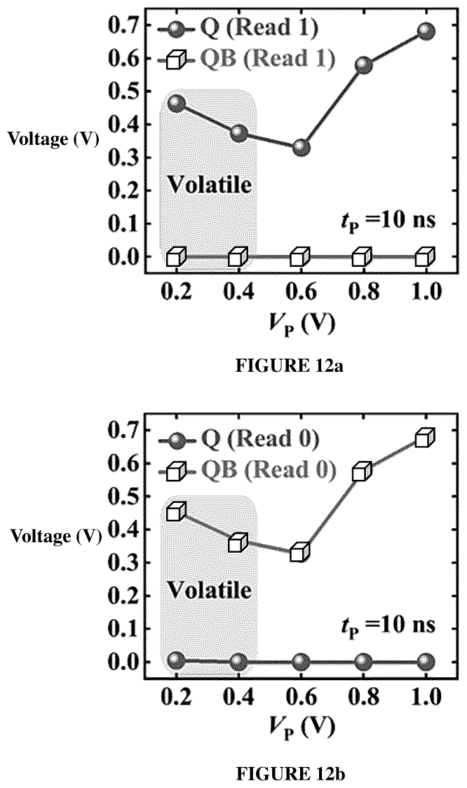

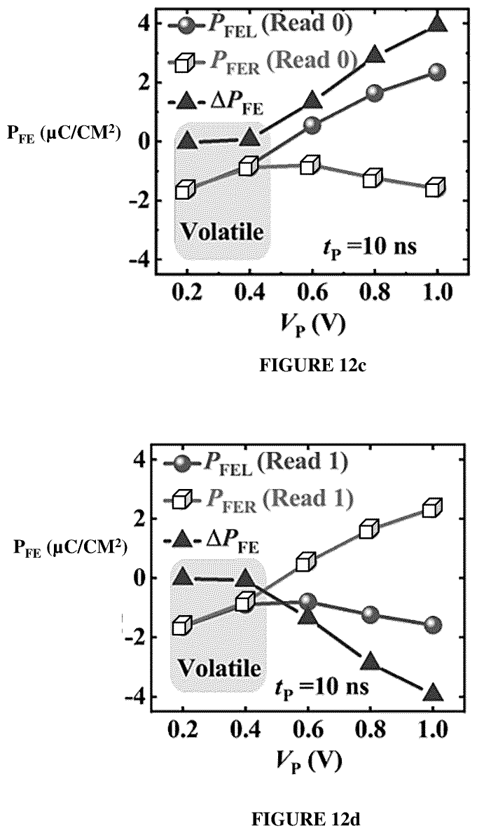

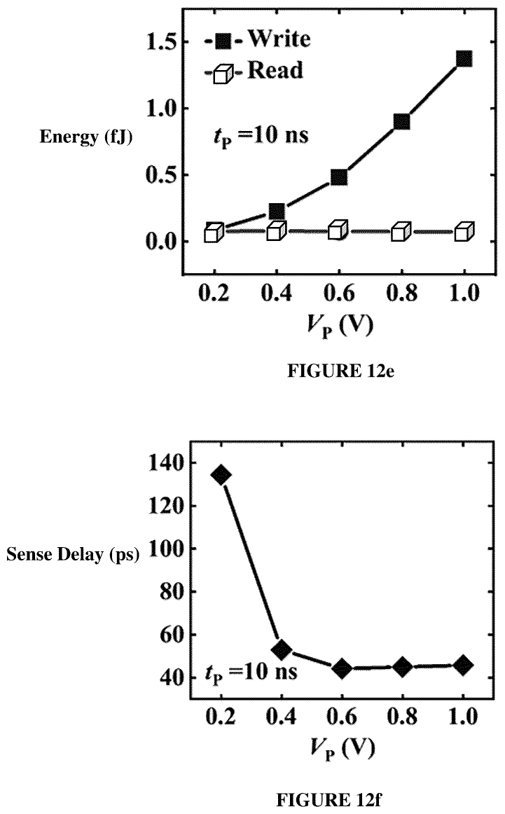

As described above, the write bias conditions influence both the performance and the operating mode of the proposed differential FeFET bit-cell. To evaluate the impact of different write conditions, the control signals applied to the bit-cell are systematically varied while the read conditions are held constant. In the following simulation, the pre-charge voltage and the sensing duration during the read operation are fixed at 1 V and 10 ns, respectively. FIGS. 12a-12f present the simulated performance of the bit-cell for a write pulse width of tₚ=10 ns, with the write voltage Vₚ=V_{w}/2 swept from 0.2 V to 1.0 V in increments of 0.2 V.

FIGS. 12a and 12b show the voltages at nodes Q and QB during read logic “1” and read logic “0” operations, respectively, under different write conditions. Based on the plots in these figures, it can be seen that the voltage difference between nodes Q and QB decreases when Vₚ≤0.6V and increases when Vₚ≥0.6V for both read logic “1” and read logic “0” cases. In order to better understand these plots, the ferroelectric polarization states of the two FeFETs, denoted as P_{FEL} and P_{FER}, are extracted and plotted in FIGS. 12c and 12d. For Vₚ=0.2 V and Vₚ=0.4 V, the polarization difference ΔP=P_{FEL}−P_{FER} was found to be approximately zero because both FeFETs remain in the same polarization state (−P_{FE}) after the write operation, indicating that polarization switching does not occur and the write operation does not alter the ferroelectric layers.

Despite the absence of polarization switching at lower write voltages, a voltage difference between nodes Q and QB can still be observed during the read operation. In this case, both FeFETs behave as transistors with high threshold voltages, and the stored information is represented by charge stored on the parasitic capacitances associated with nodes Q and QB. During the read operation, the gate-to-source voltage of FeFET NF1 is smaller than that of FeFET NF2, resulting in different discharge rates for the two nodes Q and QB. Specifically, FeFET NF1 discharges node Q more slowly than FeFET NF2 discharges node QB, thereby producing a detectable voltage difference between the differential bit lines. Accordingly, when Vₚ≤0.4V, it can be said that the proposed bit-cell operates in a volatile mode.

When Vₚ≥0.6V, the magnitude of the difference in polarization |ΔP| becomes greater than zero, indicating that the ferroelectric layers of the FeFETs are successfully programmed to different polarization states. Under these conditions, the stored data is represented by the retained polarization states of the FeFETs NF1 and NF2, and the bit-cell operates in a non-volatile mode. This behaviour demonstrates that the operating mode of the bit-cell can be configured as either volatile or non-volatile by adjusting the applied write voltage accordingly.

FIG. 12e then illustrates the write and read energy as functions of Vₚ, from which it can be observed that the write energy increases with increasing Vₚ, while the read energy is relatively insensitive to the write condition. FIG. 12f illustrates the sensing delay under different write voltages, showing a maximum sensing delay of approximately 137 ps at Vₚ=0.2V and a reduced delay of about 47 ps at higher write voltages.

These results indicate that the proposed differential FeFET bit-cell can be reliably programmed when the write voltage exceeds approximately 0.4 V, suggesting that precise control of the write voltage is not required for correct operation.

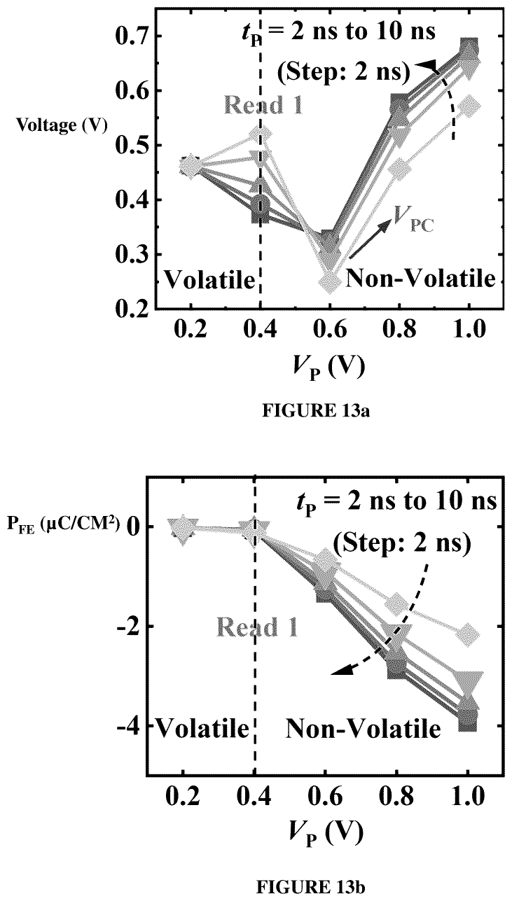

To further investigate the design space of the proposed bit-cell, the effects of varying the write pulse width ty at different values of write voltages Vy are also examined and the results are plotted in FIGS. 13a and 13b. Specifically, these two figures illustrate the memory windows (MWs) of the proposed bit-cell under different write conditions. In this simulated example, the extrinsic memory window is defined as the voltage difference between nodes Q and QB (i.e., ΔQ=V_{Q}−V_{QB}), while the intrinsic memory window is defined as the polarization difference between the two FeFETs NF1 and NF2 (i.e., ΔP=P_{FEL}−P_{FER}).

FIG. 13a shows ΔQ as measured during a read logic “1” operation under different write voltages and pulse widths. It can be seen that a trend similar to that observed in FIGS. 12a and 12b is obtained, where ΔQ decreases when Vₚ≤0.6V and increases when Vₚ≥0.6V.

For the scenario where Vₚ=0.4V and tₚ≤4 ns, the value of ΔQ is larger than that obtained at Vₚ=0.2V. This behaviour is attributed to a charge-pumping effect associated with the small parasitic capacitance of the bit-cell, which is approximately 58 aF. When Vₚ≥0.6V, ΔQ increases with both the write voltage Vₚ and the pulse width tₚ. A similar dependence is observed in FIG. 13b, where the magnitude of the polarization difference |ΔP| increases with increasing Vₚ and tₚ, consistent with the trend shown in FIG. 12d.

When Vₚ=0.4V, ΔQ increases as tₚ increases because the polarization difference ΔP at tₚ=2 ns is smaller than that obtained under longer pulse-width conditions, as indicated in FIG. 12b. In contrast, for Vₚ=0.2V, ΔQ remains nearly unchanged for different values of tₚ due to the negligible polarization difference under these conditions. These results indicate that Vₚ=0.6V represents a critical write voltage that separates volatile and non-volatile operating regimes. Collectively, the results presented in FIGS. 12 and 13 demonstrate that the proposed differential FeFET bit-cell maintains stable and reliable operation over a broad range of write voltages Vₚ and pulse widths tₚ.

TABLE 1

| Design | 6T-SRAM | | 4T-R | | 7T2R | | 8T2R | | 1T1FeFET | | Bit-cell | |
|---|---|---|---|---|---|---|---|---|---|---|---|---|
| # Transistors | 6 | | 4 | | 7 | | 8 | | 2 | | 4 | |
| Type | Simulation | | Simulation | | Experiment | | Simulation | | Experiment | | Simulation | |
| NVM device | N.A. | | R-FeFET | | ReRAM | | MTJ | | FeFET | | FeFET | |
| Store voltage | 0.74 | V | 1.1 | V | 1.8 | V | 1.2 | V | 0.9 | V | 2 | V |
| Store power | 37.12 | μW | 4.45 | mW | 0.311 | mW | 0.604 | μW | 0.134 | μW | 0.13 | μW |

| | | | | | | | | | | | |
|---|---|---|---|---|---|---|---|---|---|---|---|
| Store time | 1.92 | ns | N.A. | 10 | ns | 2 | ns | 20 | ns | 2 | ns |

| | | | | | | |
|---|---|---|---|---|---|---|
| Sense Scheme | Differential | Differential | Differential | Differential | Current-Based | Differential |
| B&E | N.A. | Not required | Required | Required | N.A. | Not required |

Table 1 above sets out a comparison of the bit-cell (i.e., far right column) described in this disclosure with conventional SRAM and other nvSRAM designs. Compared to conventional SRAM and other nvSRAM designs, the bit-cell described herein requires only four transistors. Additionally, the FeFET structure used in the bit-cell is CMOS-compatible, which eliminates the need for specialized fabrication processes. Additionally, the power stored in the bit-cell was found to be 0.13 μW, which is exceptionally low compared to existing designs. Furthermore. When the differential bit-cell described herein was compared with a state-of-the-art 1T-1FeFET gain cell, it can be seen from Table 1 that the differential bit-cell was able to achieve comparable stored power, while adopting a differential read scheme that can be directly integrated with standard SRAM sensing circuits. The storage time of the bit-cell was found to be 2 ns, which is comparable to storage times of existing 6T SRAMs. Additionally, it has also been demonstrated in the art that FeFETs tend to have high reliability and endurance (e.g., retention over 10⁴ s at 85° and endurance up to 10¹² cycles). As such, as the bit-cell utilizes such FeFETs, the bit-cell also directly benefits from such device-level improvements without requiring any modification to its circuit structure.

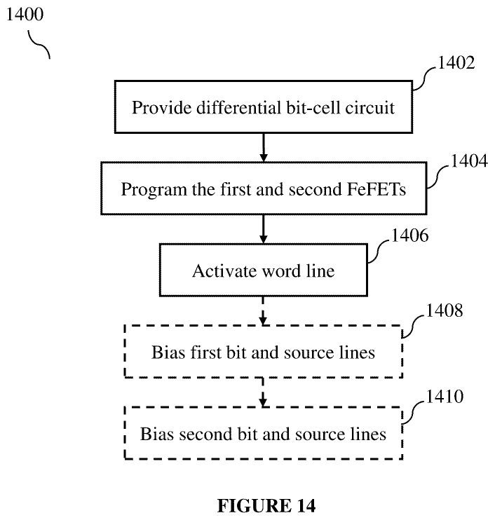

A process for operating a differential bit-cell circuit in accordance with embodiments of the disclosure is illustrated in FIG. 14. Process 1400 begins at step 1402 with process 1400 providing the differential bit-cell circuit. The differential bit-cell circuit comprises a first field-effect transistor (FET) and a second FET, wherein the first and second FETs each have a gate terminal coupled to a word line; a first ferroelectric field-effect transistor (FeFET) and a second FeFET, wherein the first and second FeFETs are cross-coupled to form a bistable latch such that a gate terminal of the first FeFET is electrically coupled to a drain terminal of the second FeFET, a gate terminal of the second FeFET is electrically coupled to a drain terminal of the first FeFET, a source terminal of the first FeFET is electrically coupled to a first source line, and a source terminal of the second FeFET is electrically coupled to a second source line, wherein the first FET is connected between the drain terminal of the first FeFET and a first bit line, and the second FET is connected between the drain terminal of the second FeFET and a second bit line. At step 1404, process 1400 then programs the first FeFET and the second FeFET to store complementary ferroelectric polarization states corresponding to complementary threshold voltages of the first FeFET and the second FeFET. Process 1400 then activates the word line to electrically couple the drain terminals of the first and second FeFETs to the first and second bit lines respectively. This takes place at step 1406.

In embodiments of the disclosure, process 1400 biases the first bit line and the first source line to a first write voltage. This takes place at step 1408. At step 1410, process 1400 then biases the second bit line and the second source line to a second write voltage different from the first write voltage, such that the first FeFET and the second FeFET are programmed with gate-to-source voltages of opposing polarity.

In embodiments of the disclosure, process 1400 may electrically decouple the first and second bit lines from the drain terminals of the first and second FeFETs respectively by de-activating of the word line, such that first and second FeFETs maintain complementary voltage levels at the drain terminals of the first and second FeFETs in accordance with the complementary threshold voltages of the first and second FeFETs.

In embodiments of the disclosure, process 1400 may bias, using a pre-charge circuit electrically coupled to the first and second bit lines, the first and second bit lines to a common pre-charge voltage; and then detect, using a voltage sensing circuit electrically coupled to the first and second bit lines, a voltage difference between the first and second bit lines.

In embodiments of the disclosure, process 1400 may bias, using a pre-charge polarization circuit electrically coupled to the first and second bit lines and the first and second source lines, the first and second bit lines and the first and second source lines to program the first and second FeFETs to a same ferroelectric polarization state, and then electrically decouple the pre-charge polarization circuit from the first and second bit lines and the first and second source lines such that, when the first and second FeFETs are in the same ferroelectric polarization state, a logic state of the bit-cell circuit is represented by complementary voltage levels at the drain terminals of the first and second FeFETs.

In embodiments of the disclosure, process 1400 may bias, using the pre-charge polarization circuit, the first and second bit lines and the first and second source lines to program the first and second FeFETs to different ferroelectric polarization states corresponding to different threshold voltages.

Numerous other changes, substitutions, variations, and modifications may be ascertained by the skilled in the art and it is intended that the present application encompass all such changes, substitutions, variations and modifications as falling within the scope of the appended claims.

1. A differential bit-cell circuit comprising:
a first field-effect transistor (FET) and a second FET, wherein the first and second FETs each have a gate terminal coupled to a word line;
a first ferroelectric field-effect transistor (FeFET) and a second FeFET, wherein the first and second FeFETs are cross-coupled to form a bistable latch such that:
a gate terminal of the first FeFET is electrically coupled to a drain terminal of the second FeFET, a gate terminal of the second FeFET is electrically coupled to a drain terminal of the first FeFET, a source terminal of the first FeFET is electrically coupled to a first source line, and a source terminal of the second FeFET is electrically coupled to a second source line,
wherein the first FET is connected between the drain terminal of the first FeFET and a first bit line, and the second FET is connected between the drain terminal of the second FeFET and a second bit line,
wherein the first FeFET and the second FeFET are programmable to store complementary ferroelectric polarization states corresponding to complementary threshold voltages of the first FeFET and the second FeFET; and
wherein, in response to activation of the word line, the first and second FETs electrically couple the drain terminals of the first and second FeFETs to the first and second bit lines respectively.

2. The differential bit-cell circuit according to claim 1, wherein the first bit line and the first source line are biased to a first write voltage, and the second bit line and the second source line are biased to a second write voltage different from the first write voltage, such that the first FeFET and the second FeFET are programmed with gate-to-source voltages of opposing polarity.

3. The differential bit-cell circuit according to claim 1, wherein in response to de-activation of the word line, the first and second FETs electrically decouple the first and second bit lines from the drain terminals of the first and second FeFETs respectively, such that first and second FeFETs maintain complementary voltage levels at the drain terminals of the first and second FeFETs in accordance with the complementary threshold voltages of the first and second FeFETs.

4. The differential bit-cell circuit according to claim 1 further comprising:
a pre-charge circuit electrically coupled to the first and second bit lines, the pre-charge circuit configured to bias the first and second bit lines to a common pre-charge voltage;
a voltage sensing circuit electrically coupled to the first and second bit lines, the voltage sensing circuit configured to detect a voltage difference between the first and second bit lines.

5. The differential bit-cell circuit according to claim 1 further comprising:
a pre-charge polarization circuit electrically coupled to the first and second bit lines and the first and second source lines, the pre-charge polarization circuit configured to bias the first and second bit lines and the first and second source lines such that the first and second FeFETs are programmed to a same ferroelectric polarization state,
wherein the pre-charge polarization circuit is electrically decouplable from the first and second bit lines and the first and second source lines such that, when the first and second FeFETs are in the same ferroelectric polarization state, a logic state of the bit-cell circuit is represented by complementary voltage levels at the drain terminals of the first and second FeFETs.

6. The differential bit-cell circuit according to claim 5, wherein the pre-charge polarization circuit is configured to bias the first and second bit lines and the first and second source lines such that the first and second FeFETs are programmed to different ferroelectric polarization states, each corresponding to different threshold voltages.

7. The differential bit-cell circuit according to claim 1, wherein the first and second FeFETs each comprise a ferroelectric electric layer comprising hafnium zirconium oxide (HZO) or lead zirconate titanate (PZT).

8. The differential bit-cell circuit according to claim 7, wherein each of the first FeFET and the second FeFET further comprises a substrate terminal coupled to a back-bias line configured to tune a threshold voltage of the first and second FeFETs.

9. The differential bit-cell circuit according to claim 1, wherein the first FET is vertically stacked with the first FeFET and the second FET is vertically stacked with the second FeFET, such that each FET and its corresponding FeFET are disposed in different device layers arranged along a vertical direction.

10. A memory array circuit comprising:
a plurality of differential bit-cell circuits according to claim 1, the plurality of differential bit-cell circuits being arranged in rows and columns, wherein differential bit-cell circuits in a same row share a common word line, and differential bit-cell circuits in a same column share a first bit line, a second bit line, a first source line, and a second source line.

11. A method for operating a differential bit-cell circuit, the method comprising:
providing the differential bit-cell circuit comprising:
a first field-effect transistor (FET) and a second FET, wherein the first and second FETs each have a gate terminal coupled to a word line;
a first ferroelectric field-effect transistor (FeFET) and a second FeFET, wherein the first and second FeFETs are cross-coupled to form a bistable latch such that a gate terminal of the first FeFET is electrically coupled to a drain terminal of the second FeFET, a gate terminal of the second FeFET is electrically coupled to a drain terminal of the first FeFET, a source terminal of the first FeFET is electrically coupled to a first source line, and a source terminal of the second FeFET is electrically coupled to a second source line, wherein the first FET is connected between the drain terminal of the first FeFET and a first bit line, and the second FET is connected between the drain terminal of the second FeFET and a second bit line,
programming the first FeFET and the second FeFET to store complementary ferroelectric polarization states corresponding to complementary threshold voltages of the first FeFET and the second FeFET; and
activating the word line to electrically couple the drain terminals of the first and second FeFETs to the first and second bit lines respectively.

12. The method according to claim 11 further comprising the step of:
biasing the first bit line and the first source line to a first write voltage; and
biasing the second bit line and the second source line to a second write voltage different from the first write voltage, such that the first FeFET and the second FeFET are programmed with gate-to-source voltages of opposing polarity.

13. The method according to claim 11 further comprising the step of:
electrically decoupling the first and second bit lines from the drain terminals of the first and second FeFETs respectively by de-activating of the word line, such that first and second FeFETs maintain complementary voltage levels at the drain terminals of the first and second FeFETs in accordance with the complementary threshold voltages of the first and second FeFETs.

14. The method according to claim 11 further comprising:
biasing, using a pre-charge circuit electrically coupled to the first and second bit lines, the first and second bit lines to a common pre-charge voltage;
detecting, using a voltage sensing circuit electrically coupled to the first and second bit lines, a voltage difference between the first and second bit lines.

15. The method according to claim 11 further comprising:
biasing, using a pre-charge polarization circuit electrically coupled to the first and second bit lines and the first and second source lines, the first and second bit lines and the first and second source lines to program the first and second FeFETs to a same ferroelectric polarization state,
electrically decoupling the pre-charge polarization circuit from the first and second bit lines and the first and second source lines such that, when the first and second FeFETs are in the same ferroelectric polarization state, a logic state of the bit-cell circuit is represented by complementary voltage levels at the drain terminals of the first and second FeFETs.

16. The method according to claim 15 further comprising:
biasing, using the pre-charge polarization circuit, the first and second bit lines and the first and second source lines to program the first and second FeFETs to different ferroelectric polarization states corresponding to different threshold voltages.

17. The method according to claim 11, wherein the first and second FeFETs each comprise a ferroelectric electric layer comprising hafnium zirconium oxide (HZO) or lead zirconate titanate (PZT).

18. The method according to claim 17, wherein each of the first FeFET and the second FeFET further comprises a substrate terminal coupled to a back-bias line configured to tune a threshold voltage of the first and second FeFETs.
